(19) United States
(12) Patent Application Publication
(10) Pub. No.: US 2026/0260857 A1
(43) Pub. Date: Sep. 3, 2026

(54) ELECTROSTATIC CHUCK ASSEMBLY

(71) Applicant: NGK Corporation, Nagoya-shi (JP)

(72) Inventors: Taro USAMI, Ginan-town (JP); Tatsuya KUNO, Nagoya-city (JP)

(21) Appl. No.: 19/655,780

(22) Filed: Apr. 23, 2026

Related U.S. Application Data
(63) Continuation of application No. PCT/JP2025/033408, filed on Sep. 22, 2025.

(30) Foreign Application Priority Data
Nov. 7, 2024 (JP) 2024-195500

(51) Int. Cl. H01J 37/32

(52) U.S. Cl. CPC H01J 37/32724; H01J 2237/002; H01J 2237/2007

(57) ABSTRACT

There is provided an electrostatic chuck assembly including a ceramic plate having a top surface on which a wafer is to be placed and a bottom surface facing the top surface and incorporating an internal electrode that is an ESC electrode and/or an RF electrode; a cooling plate mounted to the bottom surface of the ceramic plate; a plug placement hole penetrating the ceramic plate from the bottom surface to the top surface; a gas passage plug provided so as to block the plug placement hole and configured to allow gas to pass therethrough; and a gas introduction passage provided in the cooling plate and communicating with the plug placement hole. At least a part of a surface capable of coming into contact with gas inside the gas passage plug is composed of a low secondary electron emission coefficient (SEEC) material having an SEEC of 5.0 or lower.

### CROSS-REFERENCE TO RELATED APPLICATIONS

This application is a continuation application of PCT/JP2025/033408 filed September 22, 2025, which claims priority to Japanese Patent Application No. 2024-195500 filed November 7, 2024, the entire contents all of which are incorporated herein by reference.

### BACKGROUND OF THE INVENTION

### 1. Field of the Invention

The present disclosure relates to an electrostatic chuck assembly.

### 2. Description of the Related Art

Circuit formation in semiconductor device manufacturing is generally performed by plasma etching. Plasma etching is performed by introducing an inert gas into a vacuum chamber of a plasma etching apparatus and ionizing the inert gas into plasma. An electrostatic chuck assembly that functions as a susceptor on which a wafer to be etched is placed is provided in the plasma etching apparatus. The electrostatic chuck assembly includes an electrode-embedded ceramic plate that functions as an electrostatic chuck and a cooling plate that supports a bottom surface of the electrode-embedded ceramic plate. The wafer is fixed to the electrostatic chuck assembly by being electrostatically attracted to the electrode-embedded ceramic plate, and subjected to plasma etching in this state. On the other hand, the cooling plate is provided on a bottom surface of the electrode-embedded ceramic plate and is configured to dissipate heat generated on the wafer by plasma etching.

In recent years, plasma etching apparatuses have been increasingly upgraded to higher power levels to enable deep etching. In plasma etching apparatuses, a wafer is placed on an electrode-embedded ceramic plate of an electrostatic chuck assembly in order to cool and retain the shape of the wafer. In such an application as an electrostatic chuck, a gas is introduced between the wafer and the ceramic plate to increase efficiency of thermal conduction between the wafer and the ceramic plate and to reduce a contact area and suppress particle generation. In order to supply the gas, the ceramic plate is provided with a gas hole. FIG. 9 shows an example of such a conventional electrostatic chuck assembly. A conventional electrostatic chuck assembly 110 shown in FIG. 9 includes a ceramic plate 112, a cooling plate 114 mounted to the ceramic plate 112 via a bonding layer 113, a gas inlet hole 115 that penetrates the ceramic plate 112 and the cooling plate 114, and an insulating tube 117 that covers surfaces facing the gas inlet hole 115 of the bonding layer 113 and the cooling plate 114. In such a configuration, when radio frequency waves (RF) are applied to a wafer W placed on the ceramic plate 112, although the process gas above the wafer W should be ionized into plasma, plasma P caused by abnormal discharge unintentionally occurs within the gas inlet hole 115 due to effects of recent trends such as higher frequencies.

To address such problems, a method has been proposed to prevent abnormal discharge by placing a plug in a through-hole corresponding to the gas inlet hole 115. For example, Patent Literature 1 (JP2024-88883A) discloses a plug body formed from a dense ceramic material and a plug which is provided within the plug body and which includes a helical gas flow path extending from a bottom surface to a top surface of the plug body. The plug body is formed from a dense ceramic material and is therefore referred to as a dense plug. On the other hand, porous plugs are also known. Patent Literature 2 (JP7514815B) discloses a member for a semiconductor manufacturing apparatus, including: a ceramic plate; a conductive substrate provided on a bottom surface of the ceramic plate; a first hole penetrating the ceramic plate in an up-down direction; a second hole penetrating the conductive substrate in the up-down direction and communicating with the first hole; and a porous plug of which a top surface is exposed in an upper opening of the first hole and of which a bottom surface is positioned at a same height or below a top surface of the conductive substrate.

### CITATION LIST

### PATENT LITERATURE

Patent Literature 1: JP2024-88883A

Patent Literature 2: JP7514815B

### NON-PATENT LITERATURE

Non-Patent Literature 1: Sawa Araki, "Secondary Electron Emission Coefficient Measurement Technique with Scanning Auger Microprobe", Journal of Surface Analysis, Vol.11, No.2 (2004), pp.71-76

### SUMMARY OF THE INVENTION

The dense plug is arranged in the through-hole of the ceramic plate by press-fitting. FIG. 10 shows an example of a structure in which a dense plug is fixed by press-fitting. An electrostatic chuck assembly 110' shown in FIG. 10 includes: a ceramic plate 112; a cooling plate 114 mounted to the ceramic plate 112 via a bonding layer 113; a plug placement hole 116 that penetrates the ceramic plate 112 and the bonding layer 113; a gas passage plug 118 such as a dense plug that has been press-fitted into the plug placement hole 116; and a gas introduction passage 120 that is provided in the cooling plate 114 and communicates with the plug placement hole 116. According to such a configuration, the generation of plasma in the hole is suppressed as compared to a plug-less configuration such as that shown in FIG. 9. However, since a space through which gas can pass also exists within the gas passage plug 118 and there is a large potential difference between the wafer W and the cooling plate 114, a space discharge may occur.

The present inventors have recently discovered that by constructing at least a part of a surface capable of coming into contact with gas inside the gas passage plug with a low secondary electron emission coefficient (SEEC) material having an SEEC of 5.0 or lower, an electrostatic chuck assembly can be provided in which a space discharge is less likely to occur in the gas passage plug.

Accordingly, an object of the present invention is to provide an electrostatic chuck assembly in which a space discharge is less likely to occur in a gas passage plug.

The present disclosure provides the following aspects.

### Aspect 1

An electrostatic chuck assembly, comprising:

a ceramic plate having a top surface on which a wafer is to be placed and a bottom surface facing the top surface and incorporating an internal electrode that is an ESC electrode and/or an RF electrode;

a cooling plate mounted to the bottom surface of the ceramic plate;

a plug placement hole penetrating the ceramic plate from the bottom surface to the top surface;

a gas passage plug provided so as to block the plug placement hole and configured to allow gas to pass therethrough; and

a gas introduction passage provided in the cooling plate and communicating with the plug placement hole,

wherein at least a part of a surface capable of coming into contact with the gas inside the gas passage plug is composed of a low secondary electron emission coefficient (SEEC) material having an SEEC of 5.0 or lower.

### Aspect 2

The electrostatic chuck assembly according to aspect 1, wherein the secondary electron emission coefficient (SEEC) is 2.0 or lower.

### Aspect 3

The electrostatic chuck assembly according to aspect 1 or 2, wherein the low-SEEC material includes at least one selected from the group consisting of TiN, Al, brass, SiO₂, and Cr₂O₃.

### Aspect 4

The electrostatic chuck assembly according to any one of aspects 1 to 3, wherein the gas passage plug is composed of a dense body having an internal gas flow path.

### Aspect 5

The electrostatic chuck assembly according to aspect 4, wherein an entirety of the dense body is composed of the low-SEEC material.

### Aspect 6

The electrostatic chuck assembly according to aspect 4, wherein at least a part of an inner wall of the internal gas flow path is composed of the low-SEEC material.

### Aspect 7

The electrostatic chuck assembly according to aspect 6, wherein in the inner wall of the internal gas flow path, a surface of the inner wall extending in a direction that traverses an electric field generated during use is composed of the low-SEEC material.

### Aspect 8

The electrostatic chuck assembly according to aspect 6 or 7, wherein at least an inner wall portion of the internal gas flow path positioned in a vicinity of the top surface of the gas passage plug is composed of the low-SEEC material.

### Aspect 9

The electrostatic chuck assembly according to any one of aspects 6 to 8, wherein at least a part of the inner wall of the internal gas flow path includes a coating film and/or a surface modification film of the low-SEEC material.

### Aspect 10

The electrostatic chuck assembly according to any one of aspects 1 to 3, wherein the gas passage plug is composed of a porous body.

### Aspect 11

The electrostatic chuck assembly according to aspect 10, wherein an entirety of the porous body is composed of the low-SEEC material.

### Aspect 12

The electrostatic chuck assembly according to aspect 10, wherein at least a part of an inner surface of the porous body is composed of the low-SEEC material.

### Aspect 13

The electrostatic chuck assembly according to aspect 12, wherein at least an inner surface portion of the porous body positioned in a vicinity of a top surface of the gas passage plug is composed of the low-SEEC material.

### Aspect 14

The electrostatic chuck assembly according to aspect 12 or 13, wherein at least a part of the inner surface of the porous body includes a coating film and/or a surface modification film of the low-SEEC material.

### Aspect 15

The electrostatic chuck assembly according to any one of aspects 1 to 14, further comprising, in the gas introduction passage, a conductive gas passage portion in contact with a bottom surface of the gas passage plug, electrically connected to the cooling plate, and allowing passage of gas between the gas passage plug and the gas introduction passage.

### Aspect 16

The electrostatic chuck assembly according to aspect 15, wherein the conductive gas passage portion includes a leaf spring that biases the gas passage plug upward.

### BRIEF DESCRIPTION OF THE DRAWINGS

FIG. 1 is a schematic top view showing an example of an electrostatic chuck assembly according to the present invention.

FIG. 2 is a sectional view taken along line A-A of the electrostatic chuck assembly shown in FIG. 1.

FIG. 3 is a schematic sectional view showing an example of a gas passage plug to which a low-SEEC material is applied.

FIG. 4 is a schematic sectional view showing another example of a gas passage plug to which a low-SEEC material is applied.

FIG. 5 is a schematic sectional view showing another example of a gas passage plug to which a low-SEEC material is applied.

FIG. 6 is a schematic sectional view showing another example of a gas passage plug to which a low-SEEC material is applied.

FIG. 7 is a schematic perspective view showing a measurement system of plasma generation voltage for coatings of materials with various SEECs.

FIG. 8 represents a measurement result showing a relationship between plasma generation voltage and He pressure for coatings of materials with various SEECs.

FIG. 9 is a schematic section view showing an example of a conventional electrostatic chuck assembly.

FIG. 10 is a schematic section view showing an example of an electrostatic chuck assembly not according to the present invention.

### DETAILED DESCRIPTION OF THE INVENTION

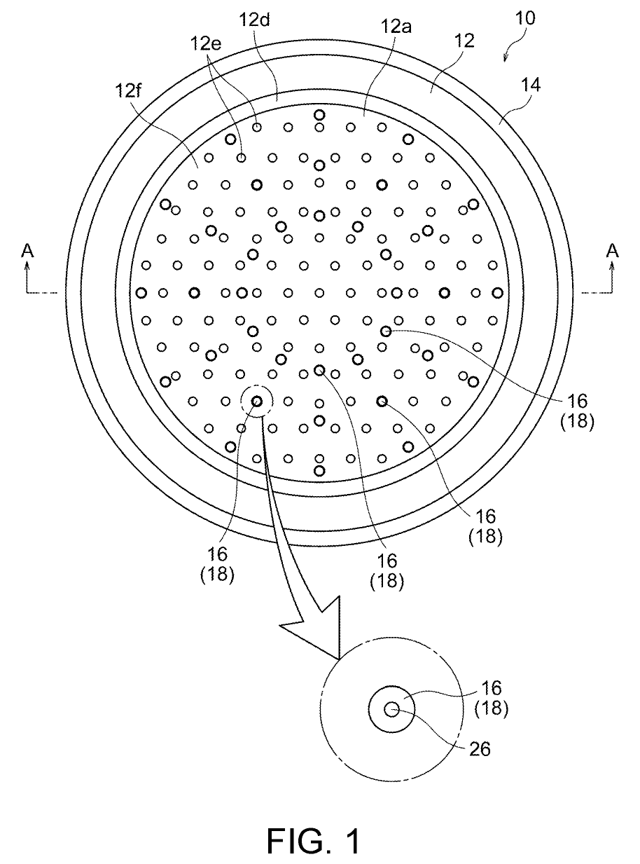

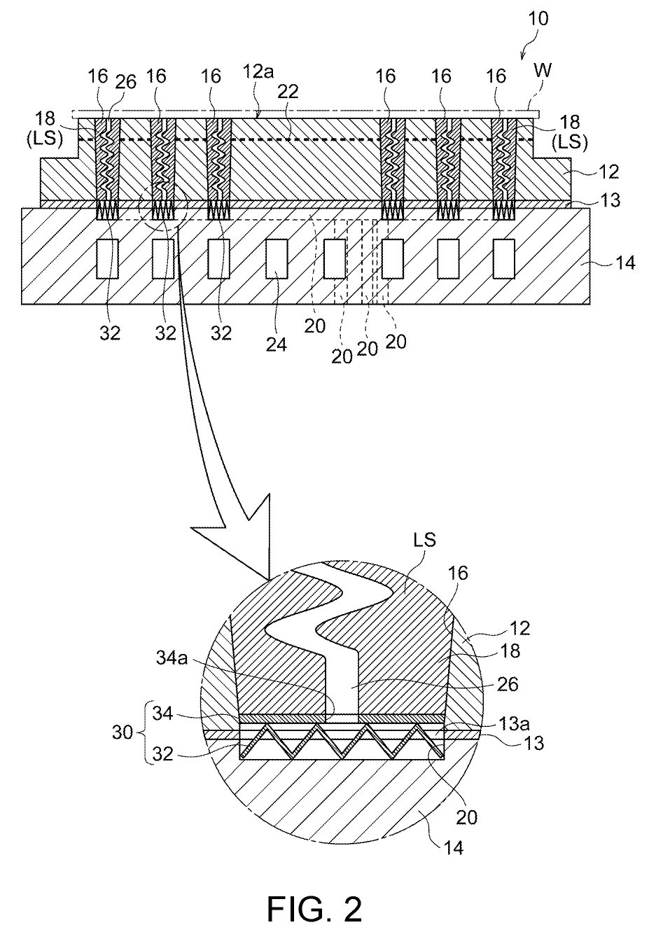

FIGS. 1 and 2 show an example of an electrostatic chuck assembly. An electrostatic chuck assembly 10 shown in FIGS. 1 and 2 includes a ceramic plate 12, a cooling plate 14, a plug placement hole 16, a gas passage plug 18, and a gas introduction passage 20. The ceramic plate 12 has a top surface 12a on which a wafer W is to be placed and a bottom surface 12b facing the top surface 12a. In addition, the ceramic plate 12 incorporates an internal electrode 22 that is an ESC electrode and/or an RF electrode. The cooling plate 14 is mounted to the bottom surface 12b of the ceramic plate 12. The plug placement hole 16 penetrates the ceramic plate 12 from the bottom surface 12b to the top surface 12a. The gas passage plugs 18 is configured to allow gas to pass therethrough and is provided so as to block the plug placement hole 16. The gas introduction passage 20 is provided in the cooling plate 14 and communicates with the plug placement hole 16. In addition, at least a part of a surface capable of coming into contact with gas inside the gas passage plug 18 is composed of a low secondary electron emission coefficient (SEEC) material LS having an SEEC of 5.0 or lower. By constructing at least, a part of a surface capable of coming into contact with gas inside the gas passage plug 18 with the low-SEEC material LS in this manner, an electrostatic chuck assembly 10 can be provided in which a space discharge is less likely to occur in the gas passage plug 18.

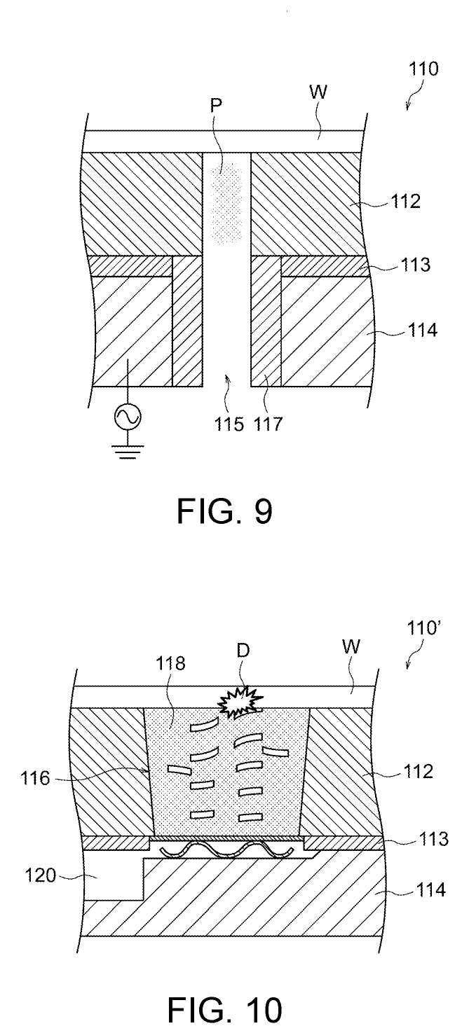

As described earlier, the dense plug is arranged in the through-hole of the ceramic plate by press-fitting. According to the electrostatic chuck assembly 110' shown in FIG. 10 that is configured in such a manner, while the generation of plasma in the hole is suppressed as compared to a plug-less configuration such as that shown in FIG. 9, since a space through which gas can pass also exists within the gas passage plug 118 and there is a large potential difference between the wafer W and the cooling plate 114, a space discharge D may occur. To address this problem, the present inventors focused on the secondary electron emission coefficient (SEEC). SEEC is an index defined as a ratio of the number of secondary electrons emitted from a sample to the number of electrons (primary electrons) incident on the sample. Furthermore, the present inventors experimentally determined that the space discharge described above is influenced by SEEC and that discharge voltage decreases as SEEC increases. Based on this finding, in the present invention, forming at least a part of a surface capable of coming into contact with gas inside the gas passage plug 18 with a low-SEEC material having an SEEC of 5.0 or lower enables an occurrence of a space discharge in the gas passage plug 18 to be suppressed.

The electrostatic chuck assembly 10 is used as a table on which the wafer is to be placed when subjecting the wafer W to CVD, etching, and the like using plasma, and is typically fixed in a vacuum chamber for manufacturing semiconductor devices.

The ceramic plate 12 may be of a configuration generally used as an electrostatic chuck. Therefore, the ceramic plate 12 incorporates an internal electrode 22 that is an ESC electrode (electrostatic electrode) and/or an RF electrode. A typical electrode-embedded ceramic plate 12 includes a disk-shaped ceramic base body and an internal electrode 22 embedded parallel to a top surface 12a or a bottom surface 12b at a predetermined height position in the ceramic base body. Examples of a ceramic material constituting the ceramic base body include aluminum nitride, silicon carbide, silicon nitride, and aluminum oxide. For example, the ceramic plate 12 may be a disk (for example, with a diameter of 300 mm and a thickness of 5 mm) made of a ceramic sintered compact such as an aluminum oxide sintered compact or an aluminum nitride sintered compact.

An annular sealing band 12d may be formed along an outer edge of the top surface 12a of the ceramic plate 12. A plurality of small circular protrusions 12e may be formed separated from each other over an entire inside region of the sealing band 12d. In this case, the sealing band 12d and the small circular protrusions 12e preferably have a same height and the height may be, for example, several μm to several tens of μm.

The internal electrode 22 can be a planar mesh electrode generally used as an ESC electrode or an RF electrode and may be connected to an external DC power supply via a power feeding member (not illustrated). A low-pass filter may be arranged along the power feeding member. The power feeding member is desirably electrically insulated from the cooling plate 14 and, if present, the conductive bonding layer 13. When a DC voltage is applied to the internal electrode 22, the wafer W is fixed by an electrostatic attraction force to the top surface 12a (specifically, a top surface of the sealing band 12d and top surfaces of the small circular protrusions 12e), and when the application of the DC voltage is removed, the wafer W is released from its attraction and fixation to the top surface 12a. Note that a portion of the top surface 12a in which the sealing band 12d and the small circular protrusions 12e are not provided will be referred to as a reference surface 12f.

The ceramic plate 12 may further incorporate a heater electrode. In this case, the heater electrode is fabricated from a conductive coil or a printed pattern and may be formed to extend from one end to another end across the entire ceramic plate 12 in a single continuous path in a plan view. The one end and the other end of the heater electrode may be connected to a pair of feeding rods (not illustrated) that penetrate the cooling plate 14 and the bonding layer 13 and inserted into the ceramic base body. The heater electrode may be configured so that a voltage is applied thereto via the feeding rods.

The cooling plate 14 is mounted to the bottom surface 12b of the ceramic plate 12. The cooling plate 14 may be a disk (a disk with a same diameter as or a larger diameter than the ceramic plate 12) with favorable thermal conductivity. A refrigerant flow path 24 through which a refrigerant circulates may be formed inside the cooling plate 14. The refrigerant that flows through the refrigerant flow path 24 is preferably a liquid and more preferably a liquid with electrical insulating properties. Examples of a liquid with electrical insulating properties include a fluorinated inert liquid. The refrigerant flow path 24 is formed to extend from one end (inlet) to another end (outlet) across the entire cooling plate 14 in a single path in a plan view. A supply port and a collection port of an external refrigerant apparatus (not illustrated) are connected to the one end and the other end of the refrigerant flow path 24, respectively. The refrigerant supplied to one end of the refrigerant flow path 24 from the supply port of the external refrigerant apparatus passes through the refrigerant flow path 24, returns to the collection port of the external refrigerant apparatus from the other end of the refrigerant flow path 24, and, after temperature adjustment, is once again supplied to the one end of the refrigerant flow path 24 from the supply port.

The cooling plate 14 may be made of a metallic material or a composite material of metal and ceramics. Examples of the metallic material include Al, Ti, Mo, and alloys thereof. Examples of the composite material of metal and ceramics include a metal matrix composite (MMC) and a ceramic matrix composite (CMC). Preferable examples of such composite materials include materials containing Si, SiC, and Ti (also referred to as SiSiCTi), materials in which Al and/or Si are impregnated into a SiC porous body, and composites of Al₂O₃ and TiC. The material constituting the cooling plate 14 should preferably be selected to have a thermal expansion coefficient close to that of the material constituting the ceramic plate 12 (in particular, the ceramic base body). Such a cooling plate 14 may be a conductive plate. Therefore, the cooling plate 14 can also be used as an RF electrode. In this case, an upper electrode (not illustrated) is arranged at a position separated upward from the ceramic plate 12 (in particular, the top surface 12a), and by applying high-frequency power between the upper electrode and the cooling plate 14 arranged parallel to each other, plasma can be generated.

The cooling plate 14 is preferably bonded to the bottom surface 12b of the ceramic plate 12 via the bonding layer 13. The bonding layer 13 may be a conductive bonding layer. The bonding layer 13 may be a bonding sheet or a metal layer such as an aluminum alloy layer. In particular, when the cooling plate 14 is fabricated from a metal matrix composite (MMC) such as SiSiCTi, the cooling plate 14 is preferably bonded to the bottom surface 12b of the ceramic plate 12 by TCB (Thermal Compression Bonding). TCB refers to a known method involving sandwiching a metal bonding material between two members that are bonding objects and pressing together while heating the two members to a temperature below a solidus temperature of the metal bonding material. Examples of the metal bonding material include aluminum alloys.

The plug placement hole 16 is a hole that penetrates the ceramic plate 12 from the bottom surface 12b to the top surface 12a. The plug placement hole 16 functions as a gas passage from the bottom surface 12b to the top surface 12a (in particular, the reference surface 12f) of the ceramic plate 12. One plug placement hole 16 may be provided, but a plurality of plug placement holes 16 are preferably provided as shown in FIG. 1. While 36 plug placement holes 16 are shown in FIG. 1, the number of plug placement holes 16 is not limited thereto. The gas passage plug 18 is embedded in each plug placement hole 16.

While an opening diameter in a horizontal direction of the plug placement hole 16 (meaning an equivalent diameter if a cross-section of the plug placement hole is not circular) is not particularly limited, for example, the opening diameter typically ranges from 1 to 5 mm at any height position and more typically ranges from 3 to 4 mm. The diameter of the plug placement hole 16 may be constant or may vary from the bottom surface 12b to the top surface 12a (in particular, the reference surface 12f) of the ceramic plate 12. As shown in FIG. 2, preferably, the plug placement hole 16 has a tapered inner circumferential surface that tapers in diameter from top to bottom, with an upper opening area being larger than a lower opening area. Due to the plug placement hole 16 having such a tapered inner circumferential surface, the gas passage plugs 18 is more likely to stop at a predetermined height position of the plug placement hole 16 when embedding the gas passage plug 18 into the plug placement hole 16 by press-fitting. Therefore, the gas passage plugs 18 can be embedded into the plug placement hole 16 with a high positioning accuracy. In addition, since the gas passage plug 18 is difficult to remove downward but relatively easy to remove upward, there is another advantage of facilitating replacement of the gas passage plug 18. Furthermore, since creepage distance increases, an effect of suppressing electrical discharge is also expected. Therefore, the plug placement hole 16 preferably has a truncated cone-shape or a truncated pyramid-shape.

The gas passage plugs 18 is provided so as to block the plug placement hole 16 and is configured to allow gas to pass therethrough. The gas passage plugs 18 may be a dense plug composed of a dense body having an internal gas flow path 26 or a porous plug composed of a porous body. In any case, the gas passage plugs 18 preferably has a shape adapted to the plug placement hole 16 to enable embedding into the plug placement hole 16. While the gas passage plugs 18 is preferably fixed by press-fitting into the plug placement hole 16, a method of fixation is not limited thereto. For example, the gas passage plugs 18 may be fixed to the plug placement hole 16 by fixation achieved by direct baking of the ceramic constituting the gas passage plug 18 or by applying an adhesive to a side surface of the gas passage plug 18. A top surface of the gas passage plugs 18 is preferably at a same height as the reference surface 12f of the ceramic plate 12. A bottom surface of the gas passage plugs 18 may be covered with a conductive coating layer 34 which may form a part of a conductive gas passage portion 30 to be described later. The coating layer 34 may be a conductive porous layer. The bottom surface of the gas passage plugs 18 may be positioned higher than the bottom surface 12b of the ceramic plate 12, positioned at the same height as the bottom surface 12b, or positioned lower than the bottom surface 12b.

The gas passage plug 18 shown in FIGS. 1 and 2 is a dense plug composed of a dense body having the internal gas flow path 26. In the present specification, a dense body shall refer to a portion of the gas passage plug 18 of which a degree of porosity, as measured in accordance with JIS R 1634:1998, is 5% or less.

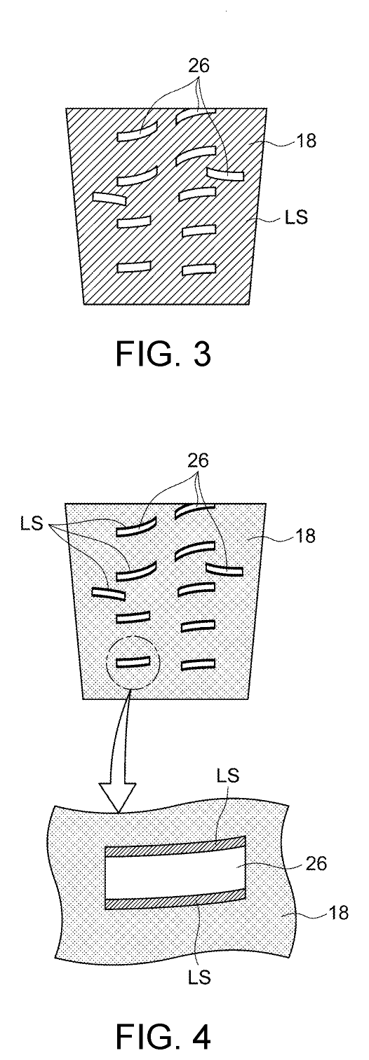

The internal gas flow path 26 is a flow path that allows flow of gas between the top surface and the bottom surface of the gas passage plug 18 as a dense plug. The internal gas flow path 26 is preferably a passage that penetrates inside the dense plug while bending from the bottom surface to the top surface and, for example, may be a zigzag-shaped passage as shown in FIG. 2 or a spiral-shaped passage as shown in FIGS. 3 to 5. The internal gas flow path 26 may be a straight through-hole along the up-down direction. A diameter of a cross-section of the internal gas flow path 26 preferably ranges from 0.1 to 1 mm. One dense plug may have a plurality of internal gas flow paths 26. A degree of porosity, as measured in accordance with JIS R 1634:1998, of a dense portion of the dense plug is preferably less than 1% and more preferably less than 0.1%. The gas passage plugs 18 as a dense plug is preferably fixed by being press-fitted into the plug placement hole 16. As the dense plug, for example, ceramics such as alumina and aluminum nitride can be used. The dense plug may be manufactured by firing a molded body formed using, for example, a 3D printer, or by firing a mold-cast molded body.

Alternatively, the gas passage plug 18 may be a porous plug composed of a porous body. In the case of a porous plug, as shown in FIG. 6, the internal gas flow path 26 described earlier need not be formed and an open pore structure of the porous body itself allows flow of gas between the top surface and the bottom surface of the gas passage plug 18. Typical examples of the porous plug include a porous bulk body obtained by sintering ceramic particles. Examples of the ceramic constituting the porous plug include alumina and aluminum nitride. A degree of porosity, as measured in accordance with the mercury intrusion method specified in JIS R 1655:2003, of the porous plug is preferably 30% or more and an average pore diameter is preferably 20 μm or more. A degree of porosity of the porous plug may be 70% or less. In addition, using porous plating, the coating layer 34 may be formed on a bottom surface of the porous plug as a metallic porous layer.

At least a part of a surface capable of coming into contact with gas inside the gas passage plug 18 is composed of a low secondary electron emission coefficient (SEEC) material LS having an SEEC of 5.0 or lower. Typically, the surface capable of coming into contact with gas inside the gas passage plug 18 is the surface of the internal gas flow path 26 in the case of a dense plug and a surface of an open pore structure in the case of a porous plug. The SEEC of the low-SEEC material LS is 5.0 or lower, preferably 2.0 or lower, and more preferably 1.0 or lower. In particular, when the SEEC is lower than 1.0, since the ceramic plate 12 and the gas passage plug 18 are oriented to absorb secondary electrons, theoretically, no discharge occurs. Even if not so, since applying a low-SEEC material with an SEEC of 5.0 or lower and preferably 2.0 or lower to a surface capable of coming into contact with gas inside the gas passage plug 18 where a space discharge may occur reduces the likelihood of electron avalanches attributable to a high SEEC, discharge voltage increases and, consequently, the occurrence of space discharges in the gas passage plug 18 can be suppressed. Examples of the low-SEEC material include TiN (SEEC: 1.3), aluminum (SEEC: 1.0), brass (SEEC: 1.5), SiO₂ (SEEC: 2.0), and Cr₂O₃ (SEEC: 1.2), which may be used alone or in combination.

As describe earlier, the secondary electron emission coefficient (SEEC) is defined as a ratio of the number of secondary electrons emitted from a sample to the number of electrons (primary electrons) incident on the sample. The SEEC can be measured according to known procedures described in, for example, Non-Patent Literature 1 (Sawa Araki, "Secondary Electron Emission Coefficient Measurement Technique with Scanning Auger Microprobe", Journal of Surface Analysis, Vol.11, No.2 (2004), pp.71-76). At this point, preferably, primary electron energy is set to 3000 eV and measurements are performed within a bias voltage range of 120 V or lower.

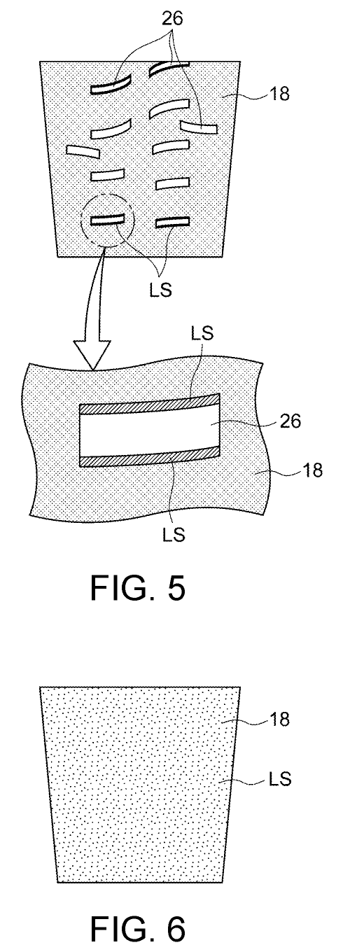

When the gas passage plug 18 is a dense plug composed of a dense body having the internal gas flow path 26, the entire dense body may be composed of the low-SEEC material LS as shown in FIGS. 2 and 3 or at least a part of an inner wall of the internal gas flow path 26 may be composed of the low-SEEC material LS as shown in FIGS. 4 and 5. In the case of the latter, as shown in FIGS. 4 and 5, the surface of the inner wall extending in a direction that traverses an electric field generated during use (for example, an approximately horizontal direction) in the inner wall of the internal gas flow path 26 is preferably composed of a low-SEEC material from the perspective of a high effect for suppressing space discharges. In this case, it can be said that the surface of the inner wall extending along the direction of the electric field generated during use (for example, an approximately perpendicular direction) need not be composed of a low-SEEC material. In other words, when the internal gas flow path 26 is viewed on a cross section perpendicular to a flow path direction, the entire inner wall surface need not be composed of a low-SEEC material LS. However, the entire inner wall surface of the internal gas flow path 26 may be composed of a low-SEEC material LS. Furthermore, while the low-SEEC material LS is applied to the inner wall of the internal gas flow path 26 across an entire thickness direction of the gas passage plug 18 from the bottom surface to the top surface in the aspect shown in FIG. 4, the low-SEEC material LS is not limited thereto. In particular, as shown in FIG. 5, at least an inner wall portion of the internal gas flow path 26 positioned in a vicinity of the top surface of the gas passage plug 18 is preferably composed of the low-SEEC material. Applying the low-SEEC material in the vicinity of the top surface of the gas passage plug 18 in this manner enables space discharge to be suppressed particularly effectively. In this case, as shown in FIG. 5, more preferably, not only the inner wall portion of the internal gas flow path 26 positioned in a vicinity of the top surface of the gas passage plug 18 but also the inner wall portion of the internal gas flow path 26 positioned in a vicinity of the bottom surface of the gas passage plug 18 is composed of the low-SEEC material. Note that a vicinity of the top surface of the gas passage plug 18 shall be understood to mean a range within 1.0 mm from the top surface of the gas passage plug 18. Similarly, a vicinity of the bottom surface of the gas passage plug 18 shall be understood to mean a range within 1.0 mm from the bottom surface of the gas passage plug 18.

A method of constructing the inner wall of the internal gas flow path 26 with the low-SEEC material LS is not particularly limited. For example, the inner wall of the internal gas flow path 26 may be coated with a low-SEEC material or a low-SEEC material may be created by applying surface modification to the inner wall of the internal gas flow path 26. Therefore, at least a part of the inner wall of the internal gas flow path 26 preferably includes a coating film and/or a surface modification film of a low-SEEC material. Examples of a method of surface modification for lowering the SEEC include sputtering and plasma CVD.

When the gas passage plug 18 is a porous plug composed of a porous body, the entire porous body may be composed of the low-SEEC material LS as shown in FIG. 6 or at least a part of an inner surface of the porous body (in other words, the surface of an open pore structure) may be composed of the low-SEEC material. In the case of the latter, at least an inner surface portion of the porous body positioned in a vicinity of the top surface of the gas passage plug 18 is composed of the low-SEEC material. Applying the low-SEEC material in a vicinity of the top surface of the gas passage plug 18 in this manner enables space discharge to be suppressed particularly effectively. In this case, more preferably, not only the inner surface portion of the porous body positioned in a vicinity of the top surface of the gas passage plug 18 but also the inner surface portion of the porous body positioned in a vicinity of the bottom surface of the gas passage plug 18 is composed of the low-SEEC material. Note that a vicinity of the top surface of the gas passage plug 18 shall be understood to mean a range within 1.0 mm from the top surface of the gas passage plug 18. Similarly, a vicinity of the bottom surface of the gas passage plug 18 shall be understood to mean a range within 1.0 mm from the bottom surface of the gas passage plug 18.

A method of constructing the inner surface of the porous body (in other words, the surface of the open pore structure) with the low-SEEC material LS is not particularly limited. For example, the inner surface of the porous body may be coated with a low-SEEC material or a low-SEEC material may be created by applying surface modification to the inner surface of the porous body. Therefore, at least a part of the inner surface of the porous body preferably includes a coating film and/or a surface modification film of a low-SEEC material. Examples of a method of surface modification for lowering the SEEC include sputtering and plasma CVD.

The gas introduction passage 20 is a passage for introducing gas which is provided in the cooling plate 14 and communicated with the plug placement hole 16. A configuration of the gas introduction passage 20 is not particularly limited as long as the gas introduction passage 20 passes through the inside of the cooling plate 14 and is capable of introducing gas to the plug placement hole 16 and, for example, as shown in FIG. 2, the gas introduction passage 20 may include a longitudinal hole extending in a longitudinal direction within the cooling plate 14 and a lateral hole communicating with the longitudinal hole and extending in a lateral direction within the cooling plate 14. In a mode including the bonding layer 13, the gas introduction passage 20 may also include a bonding layer through-hole 13a provided in the bonding layer 13 as a part of a gas passage in addition to the gas passage provided in the cooling plate 14. In a similar manner, in a mode having the coating layer 34, a coating layer through-hole 34a provided in the coating layer 34 may also form a part of a gas passage. In this manner, the gas introduction passage 20 is configured to pass through the cooling plate 14, the coating layer 34 (when present), and the bonding layer 13 (when present) and to be capable of introducing gas to the plug placement hole 16.

A side surface of at least one of the gas passage plug 18 and the plug placement hole 16 may also be composed of the low-SEEC material LS having an SEEC of 5.0 or lower, preferably 2.0 or lower, and more preferably 1.0 or lower as described above. Accordingly, a creeping discharge on an interface between the gas passage plug 18 and the ceramic plate 12 can also be suppressed. A method of constructing the side surface of the gas passage plug 18 and/or the side surface of the plug placement hole 16 with the low-SEEC material LS is not particularly limited. For example, the side surface of the gas passage plug 18 and/or the side surface of the plug placement hole 16 may be coated with the low-SEEC material LS or a low-SEEC material may be created by applying surface modification to the side surface of the gas passage plug 18 and/or the side surface of the plug placement hole 16. Therefore, the side surface of at least one of the gas passages plug 18 and the plug placement hole 16 preferably includes a coating film and/or a surface modification film of a low-SEEC material as described above.

The electrostatic chuck assembly 10 may further include the conductive gas passage portion 30. The conductive gas passage portion 30 is configured in the gas introduction passage 20 so as to be in contact with the bottom surface of the gas passage plug 18, to be electrically connected to the cooling plate 14, and to allow passage of gas between the gas passage plug 18 and the gas introduction passage 20. Accordingly, compared to a case where a porous member with insulation properties is present on a side of the bottom surface of the gas passage plug 18, a potential difference is less likely to occur around an end portion of the gas passage plug 18 on the side of the cooling plate 14. In other words, since a current can be dissipated to the conductive cooling plate 14 via the conductive gas passage portion 30, discharge around the end portion of the gas passage plug 18 on the side of the cooling plate 14 can be suppressed. The conductive gas passage portion 30 preferably includes a leaf spring 32 that biases the gas passage plug 18 upward, and more preferably includes the conductive coating layer 34 that covers the bottom surface of the gas passage plug 18 as described earlier. Since the leaf spring 32 biases the gas passage plugs 18 upward using an elastic force, it becomes easier to secure electrical continuity from a contact point of the conductive gas passage portion 30 with the gas passage plug 18 to the cooling plate 14.

The leaf spring 32 is a conductive elastic member that biases and presses the gas passage plug 18 upward using an elastic force. The leaf spring 32 is preferably made of a metallic material, and examples of the metallic material include: Al, Ti, Mo, or alloys thereof; steel; stainless steel (for example, SUS316L); and Hastelloy®. The leaf spring 32 may be manufactured, for example, by bending a metal plate. While the leaf spring 32 in the illustrated example has a zigzag shape formed by bending a metal plate, the leaf spring 32 is not limited to this shape and may have various shapes as long as the desired function is secured.

The coating layer 34 covers the bottom surface of the gas passage plug 18 and, accordingly, the coating layer 34 is in contact with the bottom surface of the gas passage plug 18. When the gas passage plug 18 is a dense plug, the coating layer 34 is preferably formed as a dense layer and, in such a case, the coating layer 34 preferably has a coating layer through-hole 34a in which gas is permeable in the up-down direction. The coating layer through-hole 34a communicates an opening of the internal gas flow path 26 on the bottom surface of the gas passage plug 18 and the gas introduction passage 20. For example, the coating layer 34 can be manufactured in advance by forming, by sputtering, electroless plating, or the like, the coating layer 34 on the bottom surface of the gas passage plug 18 prior to press-fitting the gas passage plug 18 into the ceramic plate 12 and then opening a hole 34a. The coating layer 34 is preferably made of a metallic material, and examples of the metallic material include metals with excellent corrosion resistance such as Au, Ag, Al, Ti, stainless steel (for example, SUS316L), and Hastelloy® (a Ni-Fe-Mo alloy). When the gas passage plugs 18 is a porous plug, the coating layer 34 may be a conductive porous layer. In this case, using porous plating, the coating layer 34 may be formed on the bottom surface of the gas passage plug 18 as a metallic porous layer.

### EXAMPLES

The present invention will be further described in more detail by the following examples. However, it is to be understood that the present invention is not limited to the following examples.

### Example 1

A relationship between plasma generation voltage and He pressure was studied for a coating of aluminum that is a low-SEEC material with an SEEC of 1.0 (literature value), as follows.

### (1) Construction of Measurement System

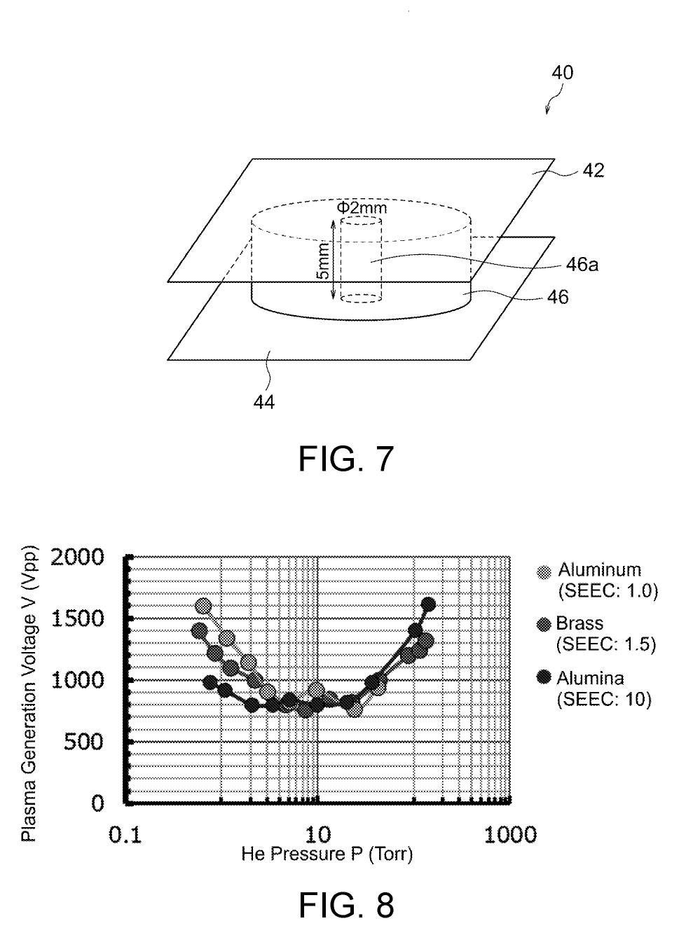

A measurement system 40 shown in FIG. 7 was prepared as follows. The measurement system 40 includes an upper electrode 42, a lower electrode 44, and an insulating member 46 interposed between the upper electrode 42 and the lower electrode 44. The upper electrode 42 and the lower electrode 44 were fabricated by laminating a 4 mm-thick alumina plate onto a surface of a brass electrode. The insulating member 46 is a transparent acrylic resin disc-shaped member with a diameter of 4 mm and a thickness of 5 mm, having a through-hole 46a with a diameter of 2 mm formed at its center. In this manner, by sandwiching and closing a cylindrical space formed at the center of the insulating member 46 with the upper electrode 42 and lower electrode 44 from above and below, a cylindrical closed space was formed for evaluating space discharge. At this point, the upper electrode 42 and the lower electrode 44 were arranged such that the aluminum coating faced the cylindrical space.

### (2) Measurement Procedure

The measurement system was placed in a vacuum chamber to which specified He pressure was introduced, and various voltages were applied to the upper electrode 42. A voltage at which light emission was confirmed in the through-hole 46a was recorded as a plasma generation voltage. Subsequently, He pressure was increased and similar tests were conducted to obtain a plasma generation voltage curve.

### (3) Measurement Results

Measurement results are shown in FIG. 8.

### Example 2

A measurement of plasma generation voltage was performed in a similar manner to Example 1, with the exception of using brass that is a low-SEEC material with an SEEC of 1.5 (literature value) instead of aluminum. Results are shown in FIG. 8.

### Example 3 (Comparison)

A measurement of plasma generation voltage was performed in a similar manner to Example 1, with the exception of using alumina that is a high-SEEC material with an SEEC of 10 (literature value) instead of aluminum. Results are shown in FIG. 8.

### Results

The results for Examples 1 to 3 shown in FIG. 8 indicate that materials with lower SEEC exhibit higher plasma generation voltages in the low He pressure range (particularly at or below 2 Torr). Specifically, aluminum with an SEEC of 1.0 exhibited the highest plasma generation voltage, followed by brass with an SEEC of 1.5 with the second-highest plasma generation voltage, while alumina with an SEEC of 10 showed the lowest plasma generation voltage. This indicates that adopting low-SEEC materials such as aluminum and brass enables the occurrence of space discharge to be significantly suppressed as compared to high-SEEC materials like alumina.

### Reference Signs List

10, 110: electrostatic chuck assembly, 12, 112: ceramic plate, 12a: top surface, 12b: bottom surface, 12d: sealing band, 12e: small circular protrusion, 12f: reference surface, 13, 113: bonding layer, 13a: bonding layer through-hole,11414, : cooling plate, 16, 116: plug placement hole, 18, 118: gas passage plug, 20,120: gas introduction passage, 22: internal electrode, 24: refrigerant flow path, 26: internal gas flow path, 30: conductive gas passage portion, 32: leaf spring, 34: coating layer, 34a: coating layer through-hole, 40: measurement system, 42: upper electrode, 44: lower electrode, 46: insulating member, 46a: through-hole, 115: gas inlet hole, 117: insulating tube, W: wafer, P: plasma, D: space discharge, LS: low-SEEC material

What is claimed is:

1. An electrostatic chuck assembly, comprising:
a ceramic plate having a top surface on which a wafer is to be placed and a bottom surface facing the top surface and incorporating an internal electrode that is an ESC electrode and/or an RF electrode;
a cooling plate mounted to the bottom surface of the ceramic plate;
a plug placement hole penetrating the ceramic plate from the bottom surface to the top surface;
a gas passage plug provided so as to block the plug placement hole and configured to allow gas to pass therethrough; and
a gas introduction passage provided in the cooling plate and communicating with the plug placement hole,
wherein at least a part of a surface capable of coming into contact with the gas inside the gas passage plug is composed of a low secondary electron emission coefficient (SEEC) material having an SEEC of 5.0 or lower.

2. The electrostatic chuck assembly according to claim 1, wherein the secondary electron emission coefficient (SEEC) is 2.0 or lower.

3. The electrostatic chuck assembly according to claim 1, wherein the low-SEEC material includes at least one selected from the group consisting of TiN, Al, brass, SiO₂ and Cr₂O₃.

4. The electrostatic chuck assembly according to claim 1, wherein the gas passage plug is composed of a dense body having an internal gas flow path.

5. The electrostatic chuck assembly according to claim 4, wherein an entirety of the dense body is composed of the low-SEEC material.

6. The electrostatic chuck assembly according to claim 4, wherein at least a part of an inner wall of the internal gas flow path is composed of the low-SEEC material.

7. The electrostatic chuck assembly according to claim 6, wherein in the inner wall of the internal gas flow path, a surface of the inner wall extending in a direction that traverses an electric field generated during use is composed of the low-SEEC material.

8. The electrostatic chuck assembly according to claim 6, wherein at least an inner wall portion of the internal gas flow path positioned in a vicinity of the top surface of the gas passage plug is composed of the low-SEEC material.

9. The electrostatic chuck assembly according to claim 6, wherein at least a part of the inner wall of the internal gas flow path includes a coating film and/or a surface modification film of the low-SEEC material.

10. The electrostatic chuck assembly according to claim 1, wherein the gas passage plug is composed of a porous body.

11. The electrostatic chuck assembly according to claim 10, wherein an entirety of the porous body is composed of the low-SEEC material.

12. The electrostatic chuck assembly according to claim 10, wherein at least a part of an inner surface of the porous body is composed of the low-SEEC material.

13. The electrostatic chuck assembly according to claim 12, wherein at least an inner surface portion of the porous body positioned in a vicinity of a top surface of the gas passage plug is composed of the low-SEEC material.

14. The electrostatic chuck assembly according to claim 12, wherein at least a part of the inner surface of the porous body includes a coating film and/or a surface modification film of the low-SEEC material.

15. The electrostatic chuck assembly according to claim 1, further comprising, in the gas introduction passage, a conductive gas passage portion in contact with a bottom surface of the gas passage plug, electrically connected to the cooling plate, and allowing passage of gas between the gas passage plug and the gas introduction passage.

16. The electrostatic chuck assembly according to claim 15, wherein the conductive gas passage portion includes a leaf spring that biases the gas passage plug upward.
